(19) United States
(12) Patent Application Publication
(10) Pub. No.: US 2011/0143549 A1
(43) Pub. Date: Jun. 16, 2011

(54) ETCHING METHOD, METHOD FOR MANUFACTURING MICROSTRUCTURE, AND ETCHING APPARATUS

(75) Inventors: Makiko TANGE, Kanagawa-ken (JP); Naoya Hayamizu, Kanagawa-ken (JP); Nobuyoshi Sato, Mie-ken (JP); Yuri Yonekura, Kanagawa-ken (JP); Hideaki Hirabayashi, Kanagawa-ken (JP); Yoshiaki Kurokawa, Kanagawa-ken (JP); Nobuo Kobayashi, Kanagawa-ken (JP); Masaaki Kato, Okayama-ken (JP); Hiroki Domon, Okayama-ken (JP)

(73) Assignees: KABUSHIKI KAISHA TOSHIBA, Tokyo (JP); SHIBAURA MECHATRONICS CORPORATION, Yokohama-shi (JP); CHLORINE ENGINEERS CORP. LTD., Chuo-ku (JP)

(21) Appl. No.: 12/963,187

(22) Filed: Dec. 8, 2010

(30) Foreign Application Priority Data
Dec. 16, 2009 (JP) 2009-285433

(51) Int. Cl. H01L 21/302; B44C 1/22; C23F 1/00; H01L 21/02

(52) U.S. Cl. 438/745; 216/83; 216/24; 216/23; 156/345.15; 257/E21.214

(57) ABSTRACT

In one embodiment, an etching method is disclosed. The method can include producing an oxidizing substance by electrolyzing a sulfuric acid solution, and producing an etching solution having a prescribed oxidizing species concentration by controlling a produced amount of the produced oxidizing substance. The method can include supplying the produced etching solution to a surface of a workpiece.

### CROSS-REFERENCE TO RELATED APPLICATIONS

This application is based upon and claims the benefit of priority from the prior Japanese Patent Application No. 2009-285433, filed on Dec. 16, 2009; the entire contents of which are incorporated herein by reference.

### FIELD

Embodiments described herein relate generally to an etching method, a method for manufacturing a microstructure, and an etching apparatus.

### BACKGROUND

In the fields of semiconductor devices and MEMS (microelectromechanical systems), microstructures with fine walls on the surface are manufactured by the lithography technique.

A resist is formed during the manufacturing process. The used resist is stripped with an SPM (sulfuric acid hydrogen peroxide mixture) solution, which is a liquid mixture of concentrated sulfuric acid and hydrogen peroxide water. The SPM solution is used also in the process of removing metals (see, e.g., JP-A-2007-123330(KOKAI)).

Here, oxidizing substances (e.g., peroxomonosulfuric acid) are produced by mixing concentrated sulfuric acid and hydrogen peroxide water. The oxidizing substances are decomposed by reacting with water. Hence, the liquid composition of the SPM solution is difficult to maintain at a constant value.

Thus, a technique is proposed for using oxidizing substances produced by electrolyzing an aqueous solution of sulfuric acid to strip a resist attached to e.g. a silicon wafer (see, e.g., JP-A-2006-111943).

By the technique disclosed in JP-A-2006-111943(KOKAI), oxidizing substances can be produced from an aqueous solution of sulfuric acid. Hence, the liquid composition of the stripping liquid can be made stable.

Here, the resist to be removed is primarily composed of organic matter, and is greatly different in composition and property from materials primarily composed of metals and metal compounds. Furthermore, the stripping liquid also needs to avoid damage to the film primarily composed of metals and metal compounds formed below the resist.

Thus, the stripping liquid containing oxidizing substances disclosed in JP-A-2006-111943(KOKAI) is not enough to be used as an etching solution for removing metals and metal compounds formed on the surface of a microstructure. On the other hand, the SPM solution can be used as an etching solution for removing metals and metal compounds. However, as described above, the liquid composition is difficult to maintain at a constant value, which may result in the failure of stable etching.

### BRIEF DESCRIPTION OF THE DRAWINGS

FIG. 1 is a schematic view for illustrating an etching apparatus according to an embodiment;

FIG. 2 is a schematic view for illustrating the concentration control means for sulfuric acid, the temperature control means for the sulfuric acid solution, and the gas processing means;

FIGS. 3A and 3B are schematic views for illustrating the production mechanism of oxidizing substances in the sulfuric acid electrolysis unit;

FIG. 4 is a graph for illustrating the temporal change of the amount of oxidizing substances (oxidizing species concentration);

FIGS. 5 and 6 are graphs for illustrating the temporal change of etching rate; and

FIG. 7 is a schematic view for illustrating an etching apparatus according to another embodiment.

### DETAILED DESCRIPTION

In one embodiment, an etching method is disclosed. The method can include producing an oxidizing substance by electrolyzing a sulfuric acid solution, and producing an etching solution having a prescribed oxidizing species concentration by controlling a produced amount of the produced oxidizing substance. The method can include supplying the produced etching solution to a surface of a workpiece.

In one embodiment, a method for manufacturing a microstructure is disclosed. The method can include forming the microstructure by removing at least one of a metal and a metal compound using an etching method. The etching method can include producing an oxidizing substance by electrolyzing a sulfuric acid solution, and producing an etching solution having a prescribed oxidizing species concentration by controlling a produced amount of the produced oxidizing substance. The method can include supplying the produced etching solution to a surface of a workpiece.

In general, according to one embodiment, an etching apparatus includes a sulfuric acid electrolysis unit, a sulfuric acid supply unit, a controller, an etching unit and an etching solution supply unit. The sulfuric acid electrolysis unit includes an anode, a cathode, a membrane provided between the anode and the cathode, an anode chamber provided between the anode and the membrane, and a cathode chamber provided between the cathode and the membrane, and the sulfuric acid electrolysis unit is configured to produce an etching solution containing an oxidizing substance by electrolyzing a sulfuric acid solution in the anode chamber to produce the oxidizing substance. The sulfuric acid supply unit is configured to supply the sulfuric acid solution to the anode chamber. The controller is configured to control a produced amount of the oxidizing substance. The etching unit is configured to etch a workpiece. The etching solution supply unit is configured to supply the etching solution to the etching unit. The controller controls the produced amount of the oxidizing substance to produce an etching solution having a prescribed oxidizing species concentration.

Embodiments of the invention will now be illustrated with reference to the drawings. In the drawings, similar components are labeled with like reference numerals, and the detailed description thereof is omitted as appropriate.

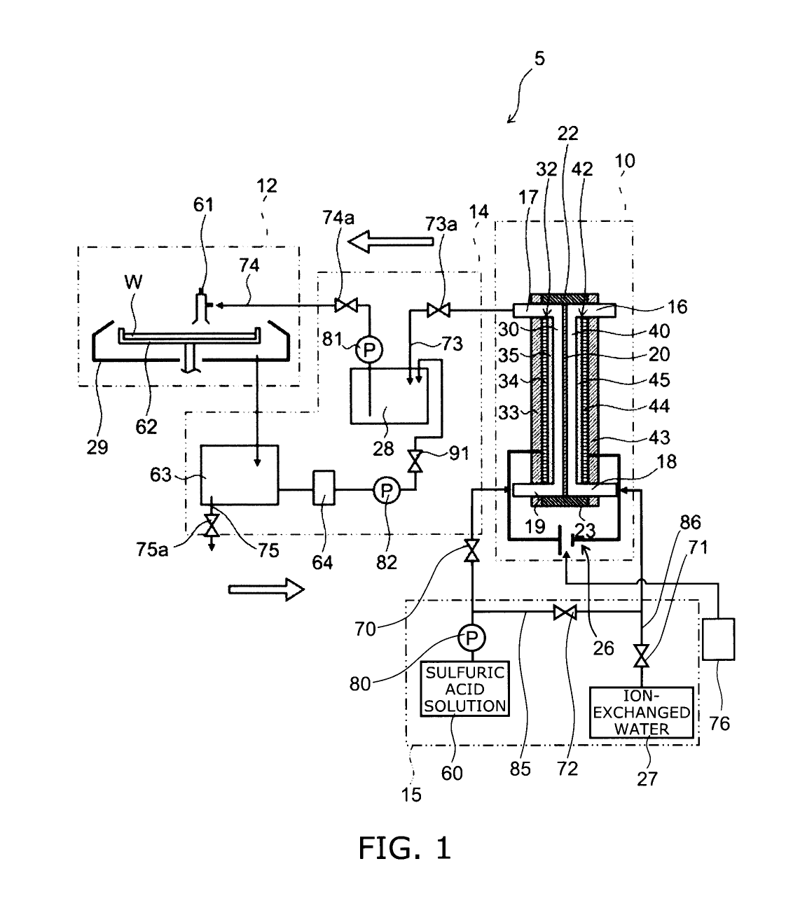

FIG. 1 is a schematic view for illustrating an etching apparatus according to an embodiment.

The etching apparatus 5 according to this embodiment includes a sulfuric acid electrolysis unit 10, an etching unit 12, an etching solution supply unit 14, a sulfuric acid supply unit 15, and a controller 76.

The sulfuric acid electrolysis unit 10 has a function of electrolyzing a sulfuric acid solution in an anode chamber 30 to produce oxidizing substances, thereby producing an etching solution containing the oxidizing substances.

The sulfuric acid electrolysis unit 10 includes an anode 32, a cathode 42, a membrane 20 provided between the anode 32 and the cathode 42, an anode chamber 30 provided between the anode 32 and the membrane 20, and a cathode chamber 40 provided between the cathode 42 and the membrane 20.

An upper end sealing portion 22 is provided at the upper end of the membrane 20, the anode chamber 30, and the cathode chamber 40. A lower end sealing portion 23 is provided at the lower end of the membrane 20, the anode chamber 30, and the cathode chamber 40. The anode 32 and the cathode 42 are opposed across the membrane 20. The anode 32 is supported on an anode support 33, and the cathode 42 is supported on a cathode support 43. A DC power supply 26 is connected between the anode 32 and the cathode 42.

The anode 32 is made of a conductive anode substrate 34 and an anode conductive film 35 formed on the surface of this anode substrate 34. The anode substrate 34 is supported on the inner surface of the anode support 33. The anode conductive film 35 faces the anode chamber 30.

The cathode 42 is made of a conductive cathode substrate 44 and a cathode conductive film 45 formed on the surface of this cathode substrate 44. The cathode substrate 44 is supported on the inner surface of the cathode support 43. The cathode conductive film 45 faces the cathode chamber 40.

An anode inlet 19 is formed on the lower end side of the anode chamber 30, and an anode outlet 17 is formed on the upper end side of the anode chamber 30. The anode inlet 19 and the anode outlet 17 are in communication with the anode chamber 30. A cathode inlet 18 is formed on the lower end side of the cathode chamber 40, and a cathode outlet 16 is formed on the upper end side of the cathode chamber 40. The cathode inlet 18 and the cathode outlet 16 are in communication with the cathode chamber 40.

The etching unit 12 has a function of etching a workpiece W using a solution (hereinafter referred to as etching solution) containing oxidizing substances produced in the sulfuric acid electrolysis unit 10.

The etching solution produced in the sulfuric acid electrolysis unit 10 is supplied from the anode outlet 17 through the etching solution supply unit 14 to a nozzle 61 provided in the etching unit 12.

The etching solution supply unit 14 has a function of supplying the etching solution to the etching unit 12. Furthermore, the etching solution supply unit 14 has also a function of recovering and reusing the etching solution ejected from the etching unit 12.

The nozzle 61 has a jetting port for jetting the etching solution to the workpiece W. A mount 62 for mounting the workpiece W is provided opposite to the jetting port. The mount 62 is provided inside a cover 29. By jetting the etching solution from the nozzle 61 toward the workpiece W, metals and metal compounds on the workpiece W can be removed. Here, the etching unit 12 illustrated in FIG. 1 is a single wafer etching unit 12. However, alternatively, the etching unit 12 may be a so-called batch etching unit for immersing a plurality of workpieces W in the etching solution.

The anode outlet 17 is connected to a tank 28 as an etching solution retainer through a line 73 provided with an open/close valve 73a. The tank 28 is connected to the nozzle 61 through a line 74. The etching solution stored and retained in the tank 28 is supplied through the line 74 to the nozzle 61 by the operation of a pump 81. Furthermore, the line 74 is provided with an open/close valve 74a on the jetting side of the pump 81. By storing and retaining the etching solution in the tank 28, the variation in the amount of the etching solution produced in the sulfuric acid electrolysis unit 10 can be buffered. Furthermore, a heater can also be provided in the tank 28. This enables temperature control of the etching solution.

The etching solution ejected from the etching unit 12 can be recovered and resupplied to the etching unit 12 by the etching solution supply unit 14. For instance, the etching solution ejected from the etching unit 12 can be passed through a returning tank 63, a filter 64, a pump 82, and an open/close valve 91 in this order and supplied to the tank 28. Then, the etching solution is supplied from the tank 28 to the etching unit 12 so that the workpiece W can be etched. Thus, in the etching, the used etching solution can be recycled and reused. Such reuse of the etching solution can be repeated as many times as possible. Thus, the amount of materials (such as chemicals) required to produce the etching solution and the amount of waste liquid can be reduced.

The returning tank 63 is provided with an drain line 75 and an ejection valve 75a so that metals and metal compounds etched away in the etching unit 12 can be ejected as necessary to the outside of the system. The filter 64 has a function of removing metals and the like contained in the etching solution ejected from the etching unit 12.

The sulfuric acid supply unit 15 has a function of supplying a sulfuric acid solution to the anode chamber 30. The sulfuric acid supply unit 15 includes a sulfuric acid tank 60 for supplying a sulfuric acid solution to the anode chamber 30, and an ion-exchanged water supply unit (tank) 27 for supplying ion-exchanged water to the cathode chamber 40. Here, the ion-exchanged water supply unit 27 can also be provided on the anode chamber 30.

The sulfuric acid tank 60 stores a sulfuric acid solution of approximately 20-70 mass percent. By the operation of a pump 80, the sulfuric acid solution in the sulfuric acid tank 60 is passed through an open/close valve 70, the line on the downstream side of the open/close valve 70, and the anode inlet 19 and supplied to the anode chamber 30. The ion-exchanged water supply unit 27 stores e.g. ion-exchanged water. The ion-exchanged water in the ion-exchanged water supply unit 27 is passed through an open/close valve 71 and the cathode inlet 18 and supplied to the cathode chamber 40. The sulfuric acid tank 60 and the ion-exchanged water supply unit 27 are connected through a line 85 and an open/close valve 72 provided thereon. The sulfuric acid solution in the sulfuric acid tank 60 is merged into an ion-exchanged water supply channel 86 through the line 85 so that the sulfuric acid solution in the sulfuric acid tank 60 is diluted with ion-exchanged water, and the diluted sulfuric acid solution is supplied to the cathode chamber 40.

For instance, a sulfuric acid solution of 30 mass percent is supplied to the anode chamber 30 through the anode inlet 19, whereas a sulfuric acid solution having a lower concentration is supplied to the cathode chamber 40 through the cathode inlet 18.

In the configuration of this embodiment, a sulfuric acid solution of approximately 20-70 mass percent is supplied from the sulfuric acid tank 60. However, as an alternative configuration, a sulfuric acid solution having a higher concentration can be supplied. For instance, a sulfuric acid solution of 96 mass percent can be supplied to the anode chamber 30 through the anode inlet 19. In this configuration, a sulfuric acid solution of 70 mass percent can be supplied to the cathode chamber 40 through the cathode inlet 18.

Even in such cases where a sulfuric acid solution having a higher concentration is supplied, the concentration of sulfuric acid supplied to the cathode side is made lower than the concentration of sulfuric acid supplied to the anode side. This can prevent damage to the membrane 20 due to electrolysis of sulfuric acid. More specifically, in the electrolysis reaction of sulfuric acid, water on the cathode side migrates to the anode side. Thus, the sulfuric acid concentration on the cathode side increases and makes the membrane 20 prone to degradation. Hence, if the sulfuric acid concentration on the cathode side is made lower, the increase of the sulfuric acid concentration on the cathode side can be suppressed. Furthermore, in the case where an ion-exchange membrane is used for the membrane 20, in a sulfuric acid solution having high concentration, the resistance of the ion-exchange membrane increases with the decrease of moisture content. This causes the problem of increased cell voltage. Also in view of alleviating this problem, the sulfuric acid concentration on the cathode side is decreased so that water is supplied to the ion-exchange membrane. Then, the increase of the resistance of the ion-exchange membrane can be suppressed.

Furthermore, the sulfuric acid supply unit 15 can be further provided with a concentration control means for sulfuric acid, a temperature control means for the sulfuric acid solution, and a gas processing means.

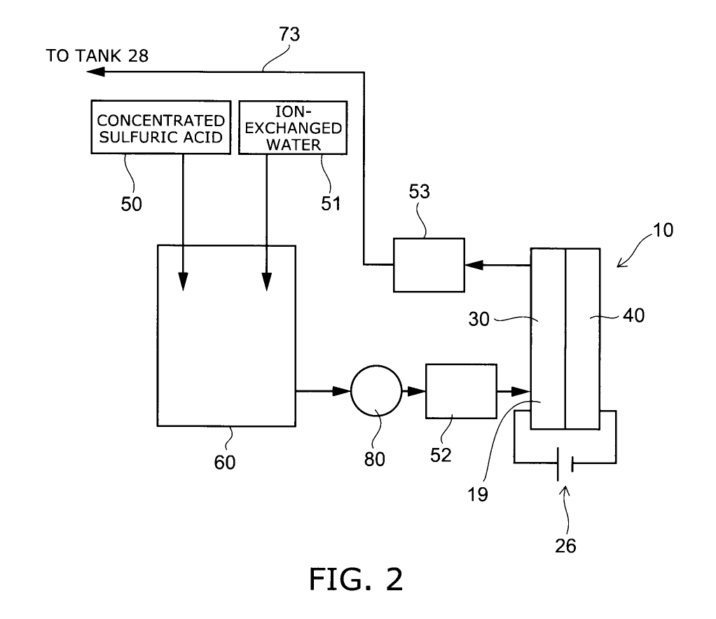

FIG. 2 is a schematic view for illustrating the concentration control means for sulfuric acid, the temperature control means for the sulfuric acid solution, and the gas processing means.

As shown in FIG. 2, in an example of the concentration control means for sulfuric acid, the sulfuric acid tank 60 is a mixture tank. The concentration control means for sulfuric acid can include a concentrated sulfuric acid supply unit 50 for supplying concentrated sulfuric acid to the mixture tank, and a dilution unit 51 for supplying ion-exchanged water for dilution to the mixture tank.

Alternatively, the concentration control means for sulfuric acid can be provided on the tank 28 for storing the etching liquid, or on the nozzle 61 or the line 73, 74.

The temperature control means for sulfuric acid can be e.g. a heat exchanger 52 provided on a line between the sulfuric acid tank 60 and the anode inlet 19.

Here, alternatively, the temperature control means for sulfuric acid can be provided inside the sulfuric acid tank 60, or provided so as to cover the anode support 33 and the like.

Furthermore, the temperature control means for sulfuric acid solution can be configured to perform heating or cooling, or heating and cooling.

The gas processing means can be e.g. a means for removing the gas produced by electrolysis (e.g., oxygen gas produced on the anode 32 side, and hydrogen gas produced on the cathode 42 side) from the electrolyte (sulfuric acid solution). For instance, the gas processing means can be e.g. a means for removing the gas by forming a liquid level for gas-liquid separation.

In this case, as illustrated in FIG. 2, a gas processor 53 for performing gas-liquid separation can be provided halfway through the line. Alternatively, the tank 28, the sulfuric acid tank 60, the anode chamber 30, and the cathode chamber 40 can be provided with a function as a gas processing means (e.g., gas-liquid separation function).

Furthermore, the aforementioned open/close valves 70, 71, 72, 73a, 74a, 75a, and 91 have also a function of controlling the flow rate of respective solutions. Furthermore, the pumps 80, 81, and 82 have also a function of controlling the flow velocity of respective solutions.

The controller 76 has a function of controlling the produced amount of oxidizing substances (oxidizing species concentration) in the sulfuric acid electrolysis unit 10 to produce an etching solution having a prescribed oxidizing species concentration. For instance, as illustrated in FIG. 1, the produced amount of oxidizing substances (oxidizing species concentration) in the sulfuric acid electrolysis unit 10 can be controlled by controlling the DC power supply 26. In this case, the DC power supply 26 is controlled to change at least one of the current value, the voltage value, and the energization time, or to change the number of electrolytic cells and the supply flow rate of the electrolyte (sulfuric acid solution). Thus, the electrolysis parameter can be controlled so as to control the produced amount of oxidizing substances (oxidizing species concentration) in the sulfuric acid electrolysis unit 10.

Alternatively, the temperature control means (e.g., the heat exchanger 52 illustrated in FIG. 2) can be controlled by the controller 76 to change the temperature of the solution in the sulfuric acid electrolysis unit 10, thereby controlling the produced amount of oxidizing substances (oxidizing species concentration). In this case, the temperature for electrolyzing the sulfuric acid solution is preferably set to 40° C. or less.

Here, it is also possible to control both the electrolysis parameter and the solution temperature.

The material of the anode support 33, the cathode support 43, the cathode outlet 16, the anode outlet 17, the cathode inlet 18, the anode inlet 19, and the cover 29 in the etching unit 12 is preferably a fluorine-based resin such as polytetrafluoroethylene in view of sulfuric acid resistance.

The line for supplying the etching solution in the etching unit 12 can be a fluorine-based resin tube wound with a heat insulator. This line can be provided with an inline heater made of a fluorine-based resin. The pump for feeding the etching solution can be a bellows pump made of a fluorine-based resin having heat resistance and oxidation resistance. The material of various tanks for containing the sulfuric acid solution can be e.g. quartz. Furthermore, these tanks can be provided with an overflow controller and a temperature controller as appropriate.

The membrane 20 can be e.g. a (hydrophilized) neutral membrane, including a PTFE porous membrane under the trade name of Poreflon, or a cation-exchange membrane under the trade names of Nafion, Aciplex, and Flemion. However, use of the latter, i.e., a cation-exchange membrane, is preferable because products in the anode chamber and the cathode chamber can be separately manufactured. The dimension of the membrane 20 can be e.g. approximately 50 square centimeters. The upper end sealing portion 22 and the lower end sealing portion 23 are preferably e.g. O-rings coated with a fluorine-based resin.

The material of the anode substrate 34 can be e.g. p-type silicon, or a valve metal such as titanium and niobium. Here, the valve metal refers to a metal with the surface uniformly covered with oxide coating by anodic oxidation and having superior corrosion resistance. The cathode substrate 44 can be made of e.g. n-type silicon.

The material of the cathode conductive film 45 can be e.g. glassy carbon. On the other hand, the anode chamber 30 may be supplied with sulfuric acid having relatively high concentration. Hence, the material of the anode conductive film 35 is preferably a conductive diamond film doped with boron, phosphorus, or nitrogen in view of durability improvement. Naturally, the material of the cathode conductive film 45 may also be a conductive diamond film. Furthermore, on both the anode side and the cathode side, the conductive film and the substrate may be formed from the same material. In this case, if the cathode substrate 44 is made of glassy carbon, or if the anode substrate 34 is made of a conductive diamond film, then the substrate itself constitutes a conductive film having electrocatalytic property, and hence can contribute to the electrolysis reaction.

Diamond is chemically, mechanically, and thermally stable, but not superior in electrical conductivity. Hence, diamond has been difficult to use in electrochemical systems. However, by the hot filament CVD (HF-CVD, hot filament chemical vapor deposition) method or the plasma CVD method, a conductive diamond film can be obtained by performing film formation while supplying boron gas or nitrogen gas. This conductive diamond film has a “potential window” of as wide as e.g. 3-5 volts, and has an electrical resistance of e.g. 5-100 milliohm centimeters.

Here, the “potential window” refers to the minimum potential (1.2 volts or more) required for electrolysis of water. This “potential window” depends on the material. In the case where a material having a wide “potential window” is used to perform electrolysis at a potential within the “potential window”, an electrolysis reaction with the redox potential in the “potential window” may proceed in preference to electrolysis of water. Thus, oxidation reaction or reduction reaction of a substance less prone to electrolysis may preferentially proceed. Hence, use of such a conductive diamond film enables decomposition and synthesis of a substance which have been impossible in the conventional electrochemical reactions.

In the HF-CVD method, film formation is performed as follows. First, a raw material gas is supplied to a tungsten filament at high temperature and decomposed to produce radicals required for film growth. Next, the produced radicals are diffused on the substrate surface, and the diffused radicals are reacted with other reactive gases to perform film formation.

Next, the production mechanism of oxidizing substances in the sulfuric acid electrolysis unit 10 is illustrated.

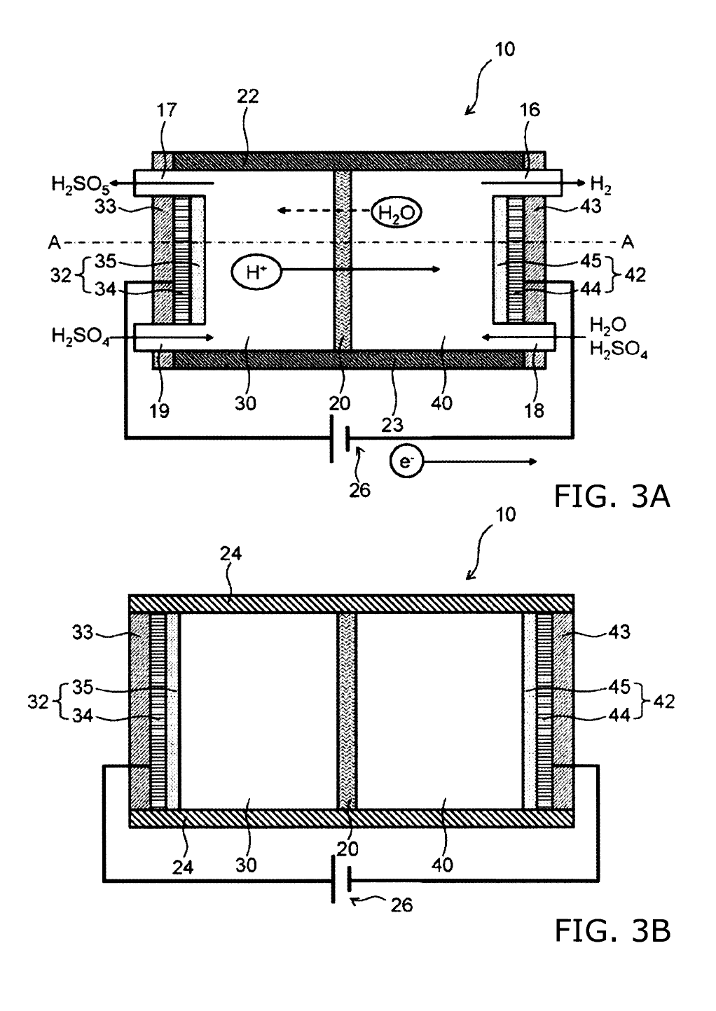

FIGS. 3A and 3B are schematic views for illustrating the production mechanism of oxidizing substances in the sulfuric acid electrolysis unit. FIG. 3B is a schematic view showing the A-A cross section in FIG. 3A.

As shown in FIG. 3B, the anode 32 and the cathode 42 are opposed across the membrane 20. The anode 32 is supported on the anode support 33 with the anode conductive film 35 facing the anode chamber 30. The cathode 42 is supported on the cathode support 43 with the cathode conductive film 45 facing the cathode chamber 40. An electrolysis unit enclosure 24 is provided at both end portions of each of the membrane 20, the anode support 33, and the cathode support 43.

The anode chamber 30 is supplied, through the anode inlet 19, with a sulfuric acid solution of e.g. 30 mass percent from the sulfuric acid tank 60. The cathode chamber 40 is supplied, through the cathode inlet 18, with the sulfuric acid solution and ion-exchanged water from the sulfuric acid tank 60 and the ion-exchanged water supply unit 27 so that the sulfuric acid concentration is made lower than that of the sulfuric acid solution.

The anode 32 is applied with a positive voltage, and the cathode 42 is applied with a negative voltage. Then, electrolysis reactions occur in each of the anode chamber 30 and the cathode chamber 40. In the anode chamber 30, such reactions as expressed in chemical formulas (1), (2), and (3) occur.

2HSO₄⁻→S₂O₈²⁻+2H⁺+2e⁻ (1)

HSO₄⁻+H₂O→HSO₅−+2H⁺+2e⁻ (2)

2H₂O→4H⁺+4e⁻+O₂↑ (3)

Hence, in the anode chamber 30, by the reaction of chemical formula (2), a peroxomonosulfate ion (HSO₅⁻) is produced. Furthermore, in another reaction, by the elementary reactions of chemical formulas (1) and (3), the overall reaction as expressed in chemical formula (4) occurs to produce a peroxomonosulfate ion (HSO₅⁻) and sulfuric acid. If a prescribed amount of this peroxomonosulfuric acid is contained in the etching solution, etching of metals and metal compounds can be accelerated.

S₂O₈²⁻+H⁺+H₂O→HSO₅⁻+H₂SO₄ (4)

Alternatively, by the elementary reactions of chemical formulas (1) and (3), hydrogen peroxide (H₂O₂) may be produced as expressed in chemical formula (5), and then the peroxomonosulfate ion (HSO₅⁻) of chemical formula (4) may be produced. Alternatively, by the reaction of chemical formula (1), peroxodisulfuric acid (H₂S₂O₈) may be produced. Chemical formulas (4) and (5) represent secondary reactions from chemical formula (1).

HSO₅⁻+H⁺+H₂O→H₂O₂+H₂SO₄ (5)

In the cathode chamber 40, as expressed in chemical formula (6), hydrogen gas is produced. This is because hydrogen ions (H⁺) produced on the anode side migrate through the membrane 20 and undergo an electrolysis reaction. The hydrogen gas is ejected from the cathode chamber 40 through the cathode outlet 16.

2H⁺+2e⁻→H₂↑ (6)

Here, peroxomonosulfuric acid (H₂SO₅) is decomposed by reacting with water, and hence exists unstably in water. Thus, the liquid composition of the etching solution changes, which may result in the failure of stable etching. Furthermore, the replacement frequency of the etching solution increases, causing the problem of increased manufacturing cost. Furthermore, such change in the liquid composition of the etching solution limits the number of workpieces per lot in the batch etching apparatus, causing the problem of low processing efficiency.

In this embodiment, by electrolyzing the sulfuric acid solution, for instance, peroxomonosulfuric acid (H₂SO₅) and peroxodisulfuric acid (H₂S₂O₈) are produced. Furthermore, although not expressed in the aforementioned chemical formulas, besides peroxomonosulfuric acid (H₂SO₅) and peroxodisulfuric acid (H₂S₂O₈), ozone and hydrogen peroxide are also produced as oxidizing substances. Hence, by electrolyzing the sulfuric acid solution, as expressed in chemical formula (7), an etching solution containing these oxidizing substances can be produced. In this case, water for decomposing the oxidizing substances (in particular, peroxomonosulfuric acid) is not produced as a byproduct, but hydrogen gas is produced as a byproduct. However, this hydrogen gas does not affect the etching process.

H₂SO₄+H₂O→Oxidizing substances+H₂ (7)

Hence, by supplying a sulfuric acid solution having high concentration (e.g., 70 mass percent) to the anode chamber 30 where oxidizing substances are produced, the oxidizing substances can be produced with a minimum amount of water. Thus, in particular, peroxomonosulfuric acid, which is decomposed by reacting with water, can be stably produced, enabling quantitative and voluminous supply of peroxomonosulfuric acid. Consequently, for instance, the etching rate and productivity can be increased, and cost reduction can also be achieved.

Here, in the case of supplying a sulfuric acid solution having low concentration (e.g., 30 mass percent) to the anode chamber 30, handling of the etching apparatus 5 is facilitated.

The concentration of the sulfuric acid solution supplied to the anode chamber 30 and the cathode chamber 40 is not limited to the concentrations illustrated above, but can be modified as appropriate.

Here, if a sulfuric acid solution of 20-70 mass percent is supplied to the anode chamber 30 irrespective of the concentration of the sulfuric acid solution supplied to the cathode chamber 40, then the production efficiency of oxidizing substances can be increased.

Here, the concentrated sulfuric acid solution and the dilute sulfuric acid solution are greatly different in characteristics. One of such characteristics is the dehydration effect. In the concentrated sulfuric acid solution, the SO₃ molecule has a dehydration effect of capturing the H₂O molecule. This significantly decreases the ratio of water molecules capable of freely reacting with other atoms and molecules. Hence, in the concentrated sulfuric acid solution, the decomposition reaction of peroxomonosulfuric acid by water can be suppressed, enabling stable production and supply of peroxomonosulfuric acid. Hence, stable production of peroxomonosulfuric acid can be achieved by supplying a concentrated sulfuric acid solution of approximately 70 mass percent to the anode chamber 30.

Next, the solution (etching solution) containing oxidizing substances produced in the sulfuric acid electrolysis unit 10 is further illustrated.

In the fields of semiconductor devices and MEMS (microelectromechanical systems), in manufacturing a microstructure, there are cases where the resist attached to the surface of the microstructure is stripped with a stripping liquid. Solutions containing oxidizing substances are known as such a stripping liquid.

However, the resist to be removed is primarily composed of organic matter, and is greatly different in composition and property from materials primarily composed of metals and metal compounds, which are to be removed in etching. Furthermore, the stripping liquid also needs to avoid damage to the film primarily composed of metals and metal compounds formed below the resist.

Thus, conventionally, the stripping liquid containing oxidizing substances cannot be used as an etching solution for removing metals and metal compounds formed on the surface of a microstructure.

As the result of investigations, the inventors have found that the oxidizing substances contained in the stripping liquid and the oxidizing substances contained in the etching solution are different in the action on the materials to be removed.

More specifically, the inventors have found that the oxidizing substances contained in the stripping liquid are used to directly dissolve the resist to be removed, whereas the oxidizing substances contained in the etching solution are used to accelerate ionization of metals and the like to be removed.

By further investigation based on such difference in the action, the inventors have found a suitable range regarding the amount of oxidizing substances contained in the etching solution.

More specifically, in the case of the stripping liquid, it is considered that the stripping performance can be improved by increasing the amount of oxidizing substances contained (to e.g. approximately 1.0 mol/L). However, in the case of the etching solution, the inventors have found that the underlying film is damaged if the amount of oxidizing substances contained is increased as in the case of the stripping liquid.

According to the inventors' findings, favorable etching can be performed if the amount of oxidizing substances contained in the etching solution is set to 0.5 mol/L or less.

Furthermore, an SPM (sulfuric acid hydrogen peroxide mixture) solution, which is a liquid mixture of concentrated sulfuric acid and hydrogen peroxide water, is often used as an etching solution.

However, oxidizing substances (e.g., peroxomonosulfuric acid) are decomposed by reacting with water. Hence, the amount of oxidizing substances in the SPM solution changes, causing the problem of the temporal change of etching rate. In this case, the temporal change of etching rate may result in the failure of stable etching.

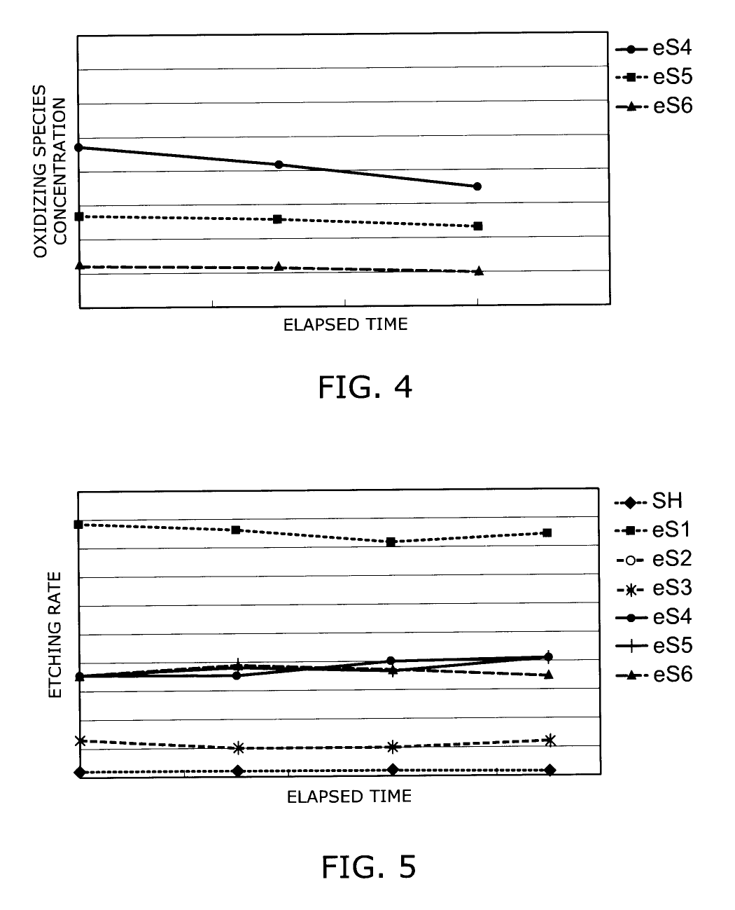

FIG. 4 is a graph for illustrating the temporal change of the amount of oxidizing substances (oxidizing species concentration).

In FIG. 4, eS4-eS6 represent etching solutions according to this embodiment. More specifically, the plot eS4 represents the case where the original oxidizing species concentration is approximately 0.5 mol/L. The plot eS5 represents the case where the original oxidizing species concentration is approximately 0.2 mol/L. The plot eS6 represents the case where the original oxidizing species concentration is approximately 0.1 mol/L.

As seen from FIG. 4, the etching solutions eS4-eS6 according to this embodiment can significantly suppress the temporal change of the oxidizing species concentration (the amount of oxidizing substances).

Hence, as compared with the case of using the SPM solution, the temporal change of etching rate can be suppressed. Thus, stable etching can be performed.

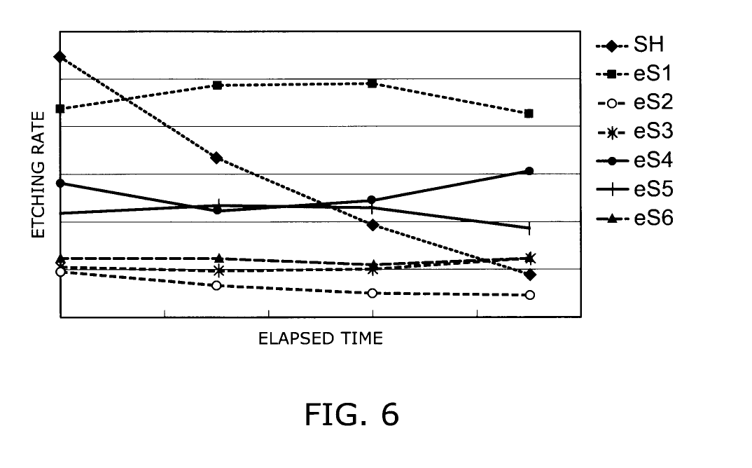

FIGS. 5 and 6 are graphs for illustrating the temporal change of etching rate.

Here, FIG. 5 shows the case where the material to be etched is a metal (FIG. 5 illustrates the case for nickel (Ni)), and FIG. 6 shows the case where the material to be etched is a metal compound (FIG. 6 illustrates the case for titanium nitride (TiN)).

Furthermore, in each figure, SH represents the SPM solution, and eS1-eS6 represent etching solutions according to this embodiment. The plots eS1-eS4 represent the cases where the original oxidizing species concentration is approximately 0.5 mol/L. The plot eS5 represents the case where the original oxidizing species concentration is approximately 0.2 mol/L. The plot eS6 represents the case where the original oxidizing species concentration is approximately 0.1 mol/L. The plots eS1-eS4 are different in the concentration of the sulfuric acid solution to be electrolyzed. The temperature of the SPM solution SH was set to approximately 120° C., and the temperature of the etching solutions eS1-eS6 was set to 100° C.

In the case of the SPM solution SH, as seen from FIG. 5, the etching rate for nickel (Ni) extremely decreases. Furthermore, as seen from FIG. 6, the etching rate for titanium nitride (TiN) significantly decreases over time.

In contrast, in the case of the etching solutions eS1-eS6 according to this embodiment, the etching rate can be made temporally stable.

Furthermore, by changing the oxidizing species concentration (the amount of oxidizing substances), a desired etching rate can be obtained. For instance, for efficient etching of a large area, the oxidizing species concentration (the amount of oxidizing substances) resulting in high etching rate can be selected. On the other hand, for accurate etching by suppressing the etching rate, the oxidizing species concentration (the amount of oxidizing substances) resulting in low etching rate can be selected. Furthermore, the etching rate can also be optimally adapted to the material to be removed.

Here, control of the oxidizing species concentration (the amount of oxidizing substances) can be performed by controlling the electrolysis parameter and temperature in the sulfuric acid electrolysis unit 10. For instance, the DC power supply 26 is controlled by the controller 76 to change at least one of the current value, the voltage value, and the energization time, or to change the number of electrolytic cells and the supply flow rate of the electrolyte (sulfuric acid solution). Thus, the electrolysis parameter can be controlled. Alternatively, the temperature control means (e.g., the heat exchanger 52 illustrated in FIG. 2) can be controlled by the controller 76 to change the temperature of the solution in the sulfuric acid electrolysis unit 10, thereby controlling the oxidizing species concentration (the amount of oxidizing substances). It is also possible to control both the electrolysis parameter and the solution temperature.

Next, the etching method according to this embodiment is illustrated along with the operation of the etching apparatus 5.

First, in the sulfuric acid electrolysis unit 10, a sulfuric acid solution is electrolyzed to produce an etching solution containing oxidizing substances (e.g., peroxomonosulfuric acid and peroxodisulfuric acid). At this time, the produced amount of the oxidizing substances (oxidizing species concentration) in the sulfuric acid electrolysis unit 10 is controlled by the controller 76. For instance, the DC power supply 26 is controlled to change at least one of the current value, the voltage value, and the energization time, or to change the number of electrolytic cells and the supply flow rate of the electrolyte (sulfuric acid solution). Thus, the electrolysis parameter is controlled so as to control the produced amount of oxidizing substances (oxidizing species concentration) in the sulfuric acid electrolysis unit 10. Alternatively, the temperature control means (e.g., the heat exchanger 52 illustrated in FIG. 2) can be controlled to change the temperature of the solution in the sulfuric acid electrolysis unit 10, thereby controlling the produced amount of oxidizing substances (oxidizing species concentration). It is also possible to control both the electrolysis parameter and the solution temperature. Here, the oxidizing species concentration is preferably set to 0.5 mol/L or less. The temperature for electrolyzing the sulfuric acid solution is preferably set to 40° C. or less.

The process in which the sulfuric acid solution is electrolyzed to produce an etching solution containing oxidizing substances is similar to that described above, and hence the description thereof is omitted.

The etching solution produced in the sulfuric acid electrolysis unit 10 is passed through the anode outlet 17 and the open/close valve 73a and stored in the tank 28. The etching solution stored in the tank 28 is supplied through the line 74 to the nozzle 61 by the operation of the pump 81. The etching solution supplied to the nozzle 61 is jetted toward a workpiece W mounted on the mount 62. Metals and metal compounds on the workpiece W are removed by the jetted etching solution. That is, etching is performed. Here, in the case of the so-called batch etching, a plurality of workpieces W are immersed in the etching solution, which is jetted from the nozzle 61 and stored.

The etching solution already used for etching is passed through the returning tank 63, the filter 64, the pump 82, and the open/close valve 91 in this order, and supplied to the tank 28 and stored therein. In this process, metals and the like contained in the etching solution already used for etching are removed by the filter 64. The etching solution stored in the tank 28 is reused for etching as described above. Furthermore, the etching solution already used for etching can also be ejected as necessary from the returning tank 63 through the drain line 75 and an ejection valve 75a to the outside of the system.

That is, in the etching method according to this embodiment, a sulfuric acid solution is electrolyzed to produce oxidizing substances. Furthermore, the produced amount of the oxidizing substances is controlled to produce an etching solution having a prescribed oxidizing species concentration. The produced etching solution is supplied to the surface of a workpiece.

Here, the oxidizing species concentration is preferably set to 0.5 mol/L or less.

The concentration of the sulfuric acid solution supplied is preferably 20 mass percent or more and 70 mass percent or less. The control of the produced amount of oxidizing substances can be performed by controlling at least one of the electrolysis parameter and temperature for electrolyzing the sulfuric acid solution.

The etching solution contains sulfuric acid not electrolyzed. The temperature for electrolyzing the sulfuric acid solution is preferably set to 40° C. or less.

Furthermore, the oxidizing species concentration can be selected in accordance with the purpose of etching.

In this case, by supplying a sulfuric acid solution having high concentration to the anode chamber 30 where oxidizing substances are produced, the oxidizing substances can be produced with a minimum amount of water. Thus, in particular, peroxomonosulfuric acid, which is decomposed by reacting with water, can be stably produced.

On the other hand, by supplying a sulfuric acid solution having low concentration to the anode chamber 30, handling of the etching apparatus 5 is facilitated.

According to this embodiment, a solution containing oxidizing substances can be used as an etching solution. This enables stable etching without temporal change of etching rate. In particular, favorable etching can be performed if the oxidizing species concentration (the amount of oxidizing substances) is set to 0.5 mol/L or less.

Furthermore, the small temporal decrease of the oxidizing species concentration (the amount of oxidizing substances) can contribute to recycling and reusing.

Furthermore, by changing the oxidizing species concentration (the amount of oxidizing substances), a desired etching rate can be obtained. For instance, for efficient etching of a large area, the oxidizing species concentration (the amount of oxidizing substances) resulting in high etching rate can be selected. On the other hand, for accurate etching by suppressing the etching rate, the oxidizing species concentration (the amount of oxidizing substances) resulting in low etching rate can be selected. Furthermore, the etching rate can also be optimally adapted to the material to be removed. Here, control of the oxidizing species concentration (the amount of oxidizing substances) can be performed by controlling the electrolysis parameter and temperature in the sulfuric acid electrolysis unit 10. This enables rapid and accurate adjustment of the oxidizing species concentration (the amount of oxidizing substances).

Consequently, the yield and productivity can be increased, and cost reduction can be achieved. Furthermore, the etching solution is recycled and reused more easily. Thus, the amount of materials (such as chemicals) required to produce the etching solution and the amount of waste liquid can be reduced.

Next, a method for manufacturing a microstructure according to this embodiment is illustrated.

The method for manufacturing a microstructure can be e.g. a method for manufacturing a semiconductor device. Here, the so-called upstream process of the method for manufacturing a semiconductor device includes the process of forming a pattern on a substrate (wafer) surface by film formation, resist application, exposure, development, etching, and resist removal, the inspection process, the cleaning process, the heat treatment process, the impurity doping process, the diffusion process, and the planarization process. Furthermore, the so-called downstream process includes the assembly process including dicing, mounting, bonding, and sealing, and the inspection process for functionality and reliability.

Here, for instance, the etching solution, the etching apparatus, and the etching method described above can be used to remove metal films used in the diffusion process.

That is, the etching solution, the etching apparatus, and the etching method described above can be used to remove at least one of a metal and a metal compound, thereby forming a microstructure.

Consequently, the yield and productivity can be increased, and cost reduction can be achieved. Here, the configuration other than the etching solution, the etching apparatus, and the etching method described above can be based on known techniques for each process, and hence the detailed description thereof is omitted.

In the foregoing, a method for manufacturing a semiconductor device is illustrated as an example of the method for manufacturing a microstructure. However, the method for manufacturing a microstructure is not limited thereto. For instance, the method for manufacturing a microstructure is also applicable to such fields as liquid crystal displays, phase shift masks, micromachines in the MEMS field, and precision optical components.

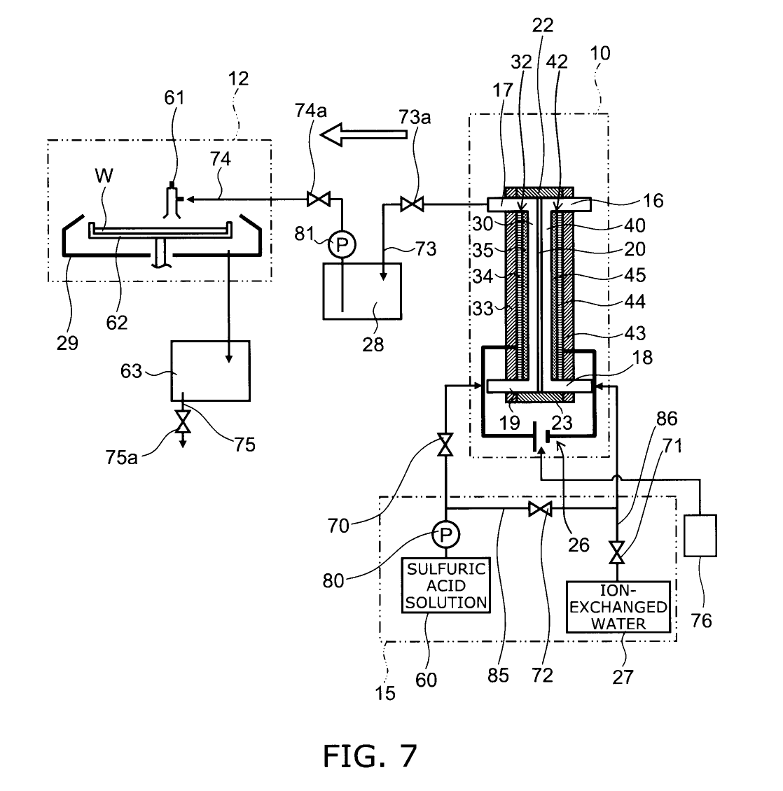

The aforementioned etching apparatus does not necessarily need to include the configuration of recycling the etching solution. As shown in FIG. 7, the etching solution already used in the etching unit 12 may be once recovered in the returning tank 63, and then ejected through the drain line 75 to the outside of the system.

Furthermore, a robot for transferring a workpiece W may be provided. Furthermore, the sulfuric acid tank 60 for storing a sulfuric acid solution may be connected to a supply line in the factory so that the sulfuric acid solution is automatically replenished with. Furthermore, a rinsing bath may be provided to rinse the etched workpiece W. This rinsing bath can be provided with an overflow controller as well as a temperature controller based on an inline heater. The material of the rinsing bath is preferably quartz.

The embodiments described above provide an etching method, a method for manufacturing a microstructure, and an etching apparatus by which stable etching can be performed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

For instance, the shape, dimension, material, layout and the like of each component of the aforementioned etching apparatus are not limited to those illustrated above, but can be modified as appropriate.

1. An etching method comprising:
producing an oxidizing substance by electrolyzing a sulfuric acid solution, and producing an etching solution having a prescribed oxidizing species concentration by controlling a produced amount of the produced oxidizing substance; and
supplying the produced etching solution to a surface of a workpiece.

2. The method according to claim 1, wherein the oxidizing species concentration is 0.5 mol/L or less.

3. The method according to claim 1, wherein the sulfuric acid solution has a concentration of 20 mass percent or more.

4. The method according to claim 1, wherein the produced amount of the oxidizing substance is controlled by controlling at least one of electrolysis parameter and temperature for electrolyzing the sulfuric acid solution.

5. The method according to claim 4, wherein the electrolysis parameter is controlled by changing at least one selected from the group consisting of current value, voltage value, energization time, number of electrolytic cells, and electrolyte supply flow rate.

6. The method according to claim 1, wherein the etching solution contains at least one selected from the group consisting of peroxomonosulfuric acid, peroxodisulfuric acid, ozone, and hydrogen peroxide.

7. The method according to claim 1, wherein the etching solution contains sulfuric acid not subjected to the electrolysis.

8. The method according to claim 1, wherein the sulfuric acid solution is electrolyzed at a temperature of 40° C. or less.

9. The method according to claim 1, wherein the oxidizing species concentration is selected in accordance with a purpose of etching.

10. The method according to claim 1, wherein the oxidizing species concentration is selected in accordance with etching rate.

11. A method for manufacturing a microstructure, comprising:
forming the microstructure by removing at least one of a metal and a metal compound using an etching method,
the etching method including:
producing an oxidizing substance by electrolyzing a sulfuric acid solution, and producing an etching solution having a prescribed oxidizing species concentration by controlling a produced amount of the produced oxidizing substance; and
supplying the produced etching solution to a surface of a workpiece.

12. The method according to claim 11, wherein the microstructure is one selected from the group consisting of a semiconductor device, a liquid crystal display, a phase shift mask, a micromachine, and an optical component.

13. An etching apparatus comprising:
a sulfuric acid electrolysis unit including an anode, a cathode, a membrane provided between the anode and the cathode, an anode chamber provided between the anode and the membrane, and a cathode chamber provided between the cathode and the membrane, the sulfuric acid electrolysis unit being configured to produce an etching solution containing an oxidizing substance by electrolyzing a sulfuric acid solution in the anode chamber to produce the oxidizing substance;
a sulfuric acid supply unit configured to supply the sulfuric acid solution to the anode chamber;
a controller configured to control a produced amount of the oxidizing substance;
an etching unit configured to etch a workpiece; and
an etching solution supply unit configured to supply the etching solution to the etching unit,
the controller controlling the produced amount of the oxidizing substance to produce an etching solution having a prescribed oxidizing species concentration.

14. The apparatus according to claim 13, wherein the controller controls the produced amount of the oxidizing substance so that the oxidizing species concentration is 0.5 mol/L or less.

15. The apparatus according to claim 13, wherein the sulfuric acid supply unit supplies the sulfuric acid solution having a concentration of 20 mass percent or more.

16. The apparatus according to claim 13, wherein the controller controls the produced amount of the oxidizing substance by controlling at least one of electrolysis parameter and temperature for electrolyzing the sulfuric acid solution.

17. The apparatus according to claim 16, wherein the controller controls the electrolysis parameter by changing at least one selected from the group consisting of current value, voltage value, energization time, number of electrolytic cells, and electrolyte supply flow rate.

18. The apparatus according to claim 16, wherein the controller performs control so that the sulfuric acid solution is electrolyzed at a temperature of 40° C. or less.

19. The apparatus according to claim 13, wherein the controller controls the produced amount of the oxidizing substance in accordance with a purpose of etching.

20. The apparatus according to claim 13, wherein the controller controls the produced amount of the oxidizing substance in accordance with etching rate.
